(19) United States
(12) Patent Application Publication
(10) Pub. No.: US 2022/0250563 A1
(43) Pub. Date: Aug. 11, 2022

(54) AUTONOMOUS DRIVING MODULE MOUNTING STRUCTURE

(71) Applicant: TOYOTA JIDOSHA KABUSHIKI KAISHA, Toyota-shi Aichi-ken (JP)

(72) Inventor: Jun Kobayashi, Toyota-shi Aichi-ken (JP)

(21) Appl. No.: 17/582,337

(22) Filed: Jan. 24, 2022

(30) Foreign Application Priority Data
Feb. 10, 2021 (JP) 2021-020136

(51) Int. Cl. B60R 16/023; H05K 5/00; B60R 11/04

(52) U.S. Cl. CPC B60R 16/0239; B60R 2011/004; B60R 11/04; H05K 5/0073

(57) ABSTRACT

An autonomous driving module mounting structure, includes a roof panel configuring an upper portion of a vehicle body, an open portion provided at the roof panel, and an autonomous driving module that includes a plurality of devices, that is mounted on an upper surface of an outer section of the roof panel, and that is disposed at a position that does not coincide with the open portion in top view.

### CROSS-REFERENCE TO RELATED APPLICATION

This application claims priority under 35 USC 119 from Japanese Patent Application No. 2021-20136 filed on Feb. 10, 2021, the disclosure of which is incorporated by reference herein in its entirety.

### BACKGROUND

### Technical Field

The present disclosure relates to an autonomous driving module mounting structure.

### Related Art

In recent years developments relating to autonomous driving technologies for vehicles have been made, and installing autonomous driving modules on roof panels configuring the upper portions of vehicle bodies is being explored. Japanese Patent Application Laid-open (JP-A) No. 2020-040657 discloses a structure for mounting an autonomous driving module inside an open portion of a roof panel provided with a sunroof.

### SUMMARY

However, in a structure for mounting an autonomous driving module inside an open portion such as described in JP-A No. 2020-040657, it is difficult to open and close the sunroof.

Thus, the present disclosure obtains an autonomous driving module mounting structure with which an autonomous driving module can be mounted on a roof panel while allowing a sunroof to be opened and closed.

An autonomous driving module mounting structure of a first aspect of the disclosure includes a roof panel configuring an upper portion of a vehicle body, an open portion provided at the roof panel, and an autonomous driving module that includes a plurality of devices, that is mounted on an upper surface of an outer section of the roof panel, and that is disposed in a position that does not coincide with the open portion in top view.

According to the autonomous driving module mounting structure of the first aspect, the autonomous driving module is mounted on the upper surface of the outer section of the roof panel and is disposed in a position that does not coincide with the open portion provided at the roof panel in top view. For that reason, when the open portion is provided with a sunroof, the autonomous driving module does not obstruct the opening and closing of the sunroof. The autonomous driving module can be mounted on the roof panel while allowing the sunroof to be opened and closed.

In an autonomous driving module mounting structure of a second aspect of the disclosure, in the first aspect, the open portion is provided with a sunroof that can be opened and closed.

According to the autonomous driving module mounting structure of the second aspect, the open portion, which is disposed in a position that does not coincide with the autonomous driving module in top view, is provided with the sunroof that can be opened and closed. The autonomous driving module does not obstruct the opening and closing of the sunroof, so the autonomous driving module can be mounted on the roof panel while allowing the sunroof to be opened and closed.

In an autonomous driving module mounting structure of a third aspect of the disclosure, in the first aspect or the second aspect, the autonomous driving module is disposed along a vehicle front-rear direction on at least one of respective sides in a vehicle width direction of the open portion in top view.

According to the autonomous driving module mounting structure of the third aspect, the autonomous driving module is disposed along the vehicle front-rear direction on at least one of respective sides in the vehicle width direction of the open portion in top view. Since the autonomous driving module is not mounted at a vehicle front side and a vehicle rear side of the open portion, a projected area from the vehicle front side can be avoided and air resistance can be reduced. Furthermore, because the autonomous driving module is not mounted at the vehicle front side and the vehicle rear side of the open portion, the autonomous driving module is unlikely to sustain damage at the time of an impact in the front-rear direction to the vehicle.

In an autonomous driving module mounting structure of a fourth aspect of the disclosure, in the first aspect or the second aspect, the autonomous driving module is disposed along a vehicle front-rear direction on at least one of respective sides in a vehicle width direction of the open portion in top view and along the vehicle width direction on at least one of respective sides in the vehicle front-rear direction of the open portion in top view.

According to the autonomous driving module mounting structure of the fourth aspect, the autonomous driving module is disposed along the vehicle front-rear direction on at least one of respective sides in the vehicle width direction of the open portion in top view and along the vehicle width direction on at least one of respective sides in the vehicle front-rear direction of the open portion in top view. Compared to the autonomous driving module mounting structure of the third aspect, the mounting area of the autonomous driving module can be increased by an amount that the autonomous driving module is disposed along the vehicle width direction on at least one of respective sides in the vehicle front-rear direction of the open portion. The number of the devices included in the autonomous driving module can be increased, so the performance of the autonomous driving module can be improved.

In an autonomous driving module mounting structure of a fifth aspect of the disclosure, in any of the first aspect to the fourth aspect, the autonomous driving module is disposed between a front pillar and a rear pillar in the vehicle front-rear direction in top view.

According to the autonomous driving module mounting structure of the fifth aspect, the autonomous driving module is disposed between the front pillar and the rear pillar in the vehicle front-rear direction in top view. The area between the front pillar and the rear pillar in the vehicle front-rear direction is included in a safety zone that has enough strength to maintain its shape even when subjected to a shock. The crash safety performance of the autonomous driving module at the time of an impact to the vehicle can be improved.

In an autonomous driving module mounting structure of a sixth aspect of the disclosure, in any of the first aspect to the fifth aspect, the upper surface of the outer section of the roof panel is provided with input/output ports to which wiring or devices from the autonomous driving module can be connected.

According to the autonomous driving module mounting structure of the sixth aspect, the upper surface of the outer section of the roof panel is provided with the input/output ports to which wiring or devices from the autonomous driving module can be connected. When, for example, the technology of sensors and the like included in the autonomous driving module has improved, the autonomous driving module can be easily updated.

In an autonomous driving module mounting structure of a seventh aspect of the disclosure, in any of the first aspect to the sixth aspect, the autonomous driving module mounting structure has at least one module case that houses the autonomous driving module, and the module case has a sloping portion that descends from a vehicle rear side to a vehicle front side in side view.

According to the autonomous driving module mounting structure of the seventh aspect, the module case that houses the autonomous driving module has the sloping portion that descends from the vehicle rear side to the vehicle front side in side view. Air resistance experienced by the vehicle from the front when the vehicle moves forward can be kept down by the sloping portion, so aerodynamic performance of the vehicle can be improved.

In an autonomous driving module mounting structure of an eighth aspect of the disclosure, in the first aspect or the second aspect, four autonomous driving modules are disposed in the vicinities of four corners of the open portion in top view. Due to this arrangement of the four autonomous driving modules, risk of damage to the devices housed inside the autonomous driving modules at a time of an impact to the vehicle can be reduced.

As described above, according to the present disclosure, an autonomous driving module mounting structure with which an autonomous driving module can be mounted on a roof panel while allowing a sunroof to be opened and closed can be obtained.

### BRIEF DESCRIPTION OF THE DRAWINGS

Embodiments will be described in detail based on the following figures, wherein:

FIG. 1 is a top view of a vehicle to which an autonomous driving module mounting structure pertaining to a first embodiment is applied;

FIG. 2 is a plan view showing an example of the configuration of an autonomous driving module;

FIG. 3 is a side view of the vehicle to which the autonomous driving module mounting structure pertaining to the first embodiment is applied;

FIG. 4 is a perspective view showing an example of the vehicle to which the autonomous driving module is mounted;

FIG. 5 is a perspective view describing a method of mounting the autonomous driving module;

FIG. 6 is a block diagram showing an example of the configuration of the autonomous driving module;

FIG. 7 is a block diagram showing an example of the overall configuration of an autonomous driving system;

FIG. 8 is a top view of the vehicle to which an autonomous driving module mounting structure pertaining to a second embodiment is applied;

FIG. 9 is a top view of the vehicle to which an autonomous driving module mounting structure pertaining to a third embodiment is applied;

FIG. 10 is a top view of the vehicle to which an autonomous driving module mounting structure pertaining to a fourth embodiment is applied;

FIG. 11 is a top view of the vehicle to which an autonomous driving module mounting structure pertaining to a fifth embodiment is applied;

FIG. 12 is a top view of the vehicle to which an autonomous driving module mounting structure pertaining to a sixth embodiment is applied;

FIG. 13 is a top view of the vehicle to which an autonomous driving module mounting structure pertaining to a seventh embodiment is applied;

FIG. 14 is a top view of the vehicle to which an autonomous driving module mounting structure pertaining to an eighth embodiment is applied;

FIG. 15 is a top view of the vehicle to which an autonomous driving module mounting structure pertaining to a ninth embodiment is applied; and

FIG. 16 is a top view of the vehicle to which an autonomous driving module mounting structure pertaining to a tenth embodiment is applied.

### DETAILED DESCRIPTION

### First Embodiment

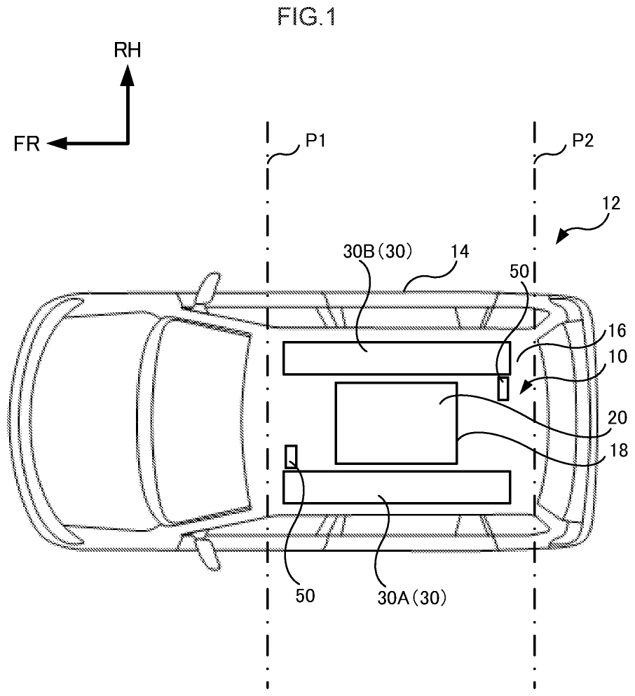

An autonomous driving module mounting structure 10 of a first embodiment pertaining to the disclosure will be described. First, the overall configuration of a vehicle 12 serving as an autonomous driving battery electric vehicle to which the autonomous driving module mounting structure 10 is applied will be described using FIG. 1 to FIG. 7. It will be noted that arrow FR appropriately shown in the drawings indicates the vehicle forward direction, arrow UP indicates the vehicle upward direction, and arrow RH indicates the rightward direction in the vehicle width direction. Furthermore, in the drawings, the sizes and shapes of a sunroof and module cases sometimes differ from their actual dimensions for convenience of description. In the following embodiment, the vehicle 12 is a minivan as an example, but the autonomous driving module mounting structure 10 can be applied to all types of vehicles so long as they are vehicles to which a sunroof can be mounted, such as ordinary passenger cars and sport utility vehicles (SUVs).

The vehicle 12 is configured to be switchable between a manual driving mode in which a driver performs driving maneuvers and an autonomous driving mode in which driving maneuvers by the driver are unnecessary. As shown in FIG. 1, the vehicle 12 has a roof panel 16 configuring an upper portion of a vehicle body 14. The roof panel 16 is provided with a rectangular open portion 18 at a middle portion in a vehicle front-rear direction and in the vehicle width direction as an example. The open portion 18 is provided with a sunroof 20 that can be opened and closed.

The sunroof 20 is made of an optically transparent material such as glass as an example, and is configured as a movable panel (not shown in the drawings) that opens and closes the open portion 18. It will be noted that the sunroof 20 may be provided with a shade panel (not shown in the drawings) that, by moving in the vehicle front-rear direction, adjusts the amount of light entering the cabin of the vehicle 12 through the open portion 18. The sunroof 20 can have the same configuration as that of commonly used sunroofs.

On an upper surface of an outer section of the roof panel 16, an autonomous driving module 30 is disposed in a position that does not coincide with the open portion 18 in top view. In this embodiment, as an example, the autonomous driving modules 30 are disposed along the vehicle front-rear direction at both sides in the vehicle width direction of the open portion 18. The autonomous driving module 30 disposed on the left side will be called a first autonomous driving module 30A, and the autonomous driving module 30 disposed on the right side will be called a second autonomous driving module 30B.

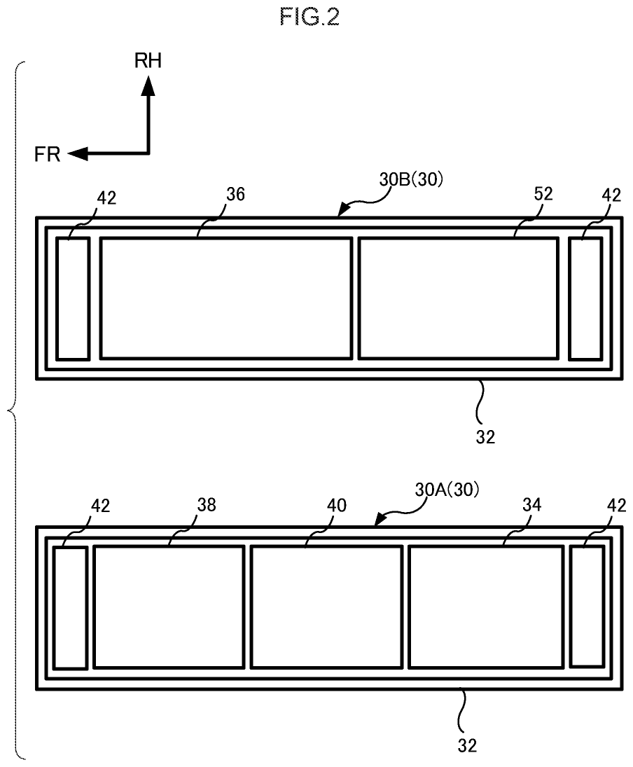

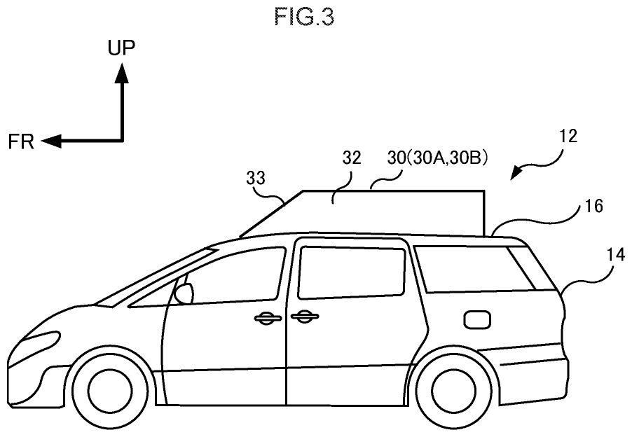

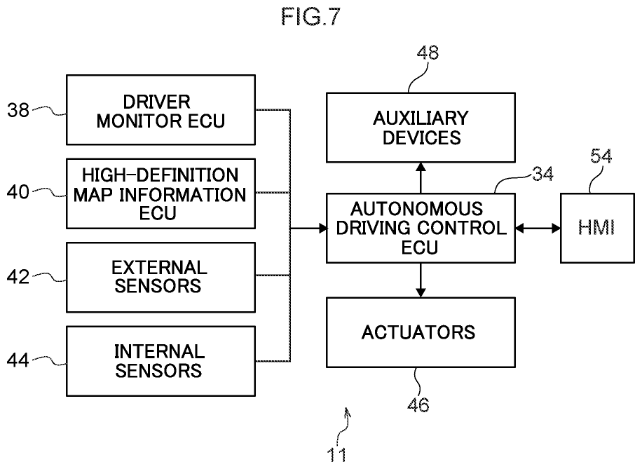

The first autonomous driving module 30A and the second autonomous driving module 30B are configured by the modularization of plural devices that are constituent devices of an autonomous driving system 11 (see FIG. 7). As shown in FIG. 2, the first autonomous driving module 30A and the second autonomous driving module 30B are each configured as a result of plural devices being housed inside a module case 32 serving as an outer shell. The module cases 32 are long hollow cuboids whose lengthwise direction coincides with the vehicle front-rear direction. As shown in FIG. 3, the module cases 32 each have a sloping portion 33 that descends from the vehicle rear side to the vehicle front side in side view.

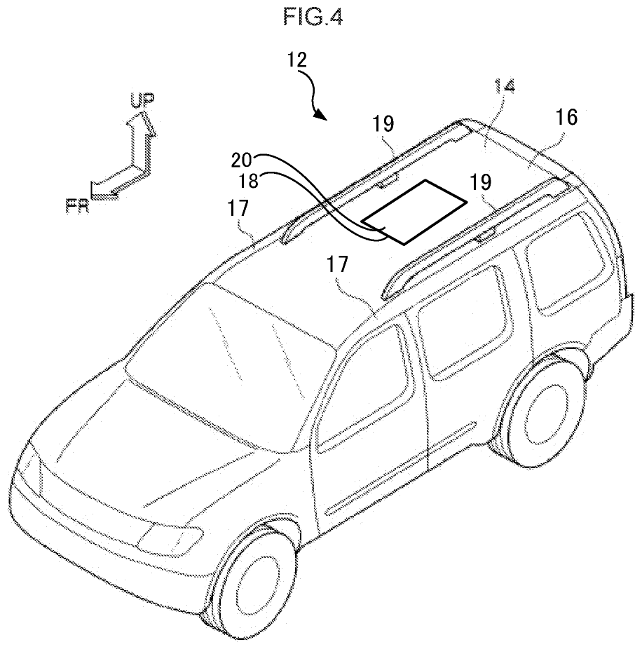

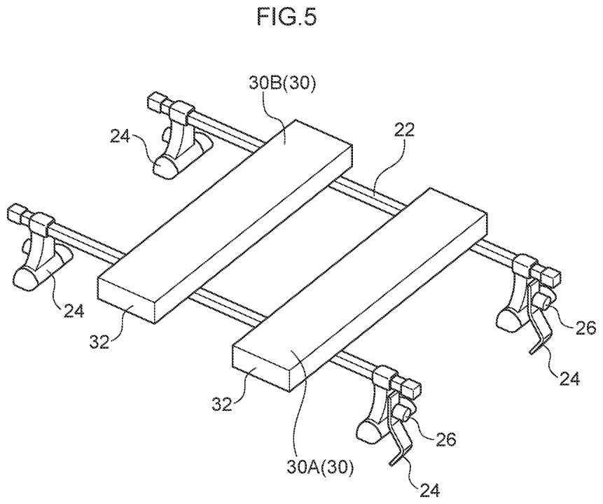

The module cases 32 are secured at the roof panel 16. As the method of securing the module cases 32 at the roof panel 16, the vehicle 12 has, as shown in FIG. 4 as an example, roof rails 19 for attaching skis and/or a storage box to the outer upper surface of the roof panel 16. The roof rails 19 are provided along side panels 17 of the vehicle 12 on both end portions in the vehicle width direction of the roof panel 16. In this case, as shown in FIG. 5, undersurfaces of the module cases 32 are secured to two rails 22 equipped at both ends with attachments 24 for detachably securing the rails 22 to the roof rails 19, and the module cases 32 are secured via the attachments 24 to the roof rails 19. The attachments 24 have structures that grip the roof rails 19 from both sides as a result of dials 26 being turned. It will be noted that the two rails 22 are disposed a distance apart from each other in the vehicle front-rear direction so as to not coincide with the open portion 18 of the roof panel 16 in top view.

Furthermore, as shown in FIG. 1, the upper surface of the outer section of the roof panel 16 is provided with input/output ports 50 to which wiring or devices from the autonomous driving module 30 can be connected. The input/output ports 50 are provided in the neighborhood of a vehicle front side and of a right side of the first autonomous driving module 30A and in the neighborhood of a vehicle rear side and of a left side of the second autonomous driving module 30B. The input/output ports 50 are provided so as to be exposed as seen from the outer side of the roof panel 16.

The autonomous driving module 30 is equipped with wire harnesses (not shown in the drawings) that are electrically connected to the devices inside the module cases 32, that have connectors (not shown in the drawings) on their distal ends, and that extend outside the module cases 32. By connecting the connectors on the distal ends of the wire harnesses (not shown in the drawings) to the input/output ports 50, the devices inside the autonomous driving module 30 become connected, via wire harnesses (not shown in the drawings) wired to the cabin of the vehicle 12, to a main battery 60 and an in-vehicle network (not shown in the drawings) described later. It will be noted that the wire harnesses (not shown in the drawings) wired to the cabin of the vehicle 12 are routed in avoidance of deployment areas of roof airbags and curtain airbags provided in the vehicle 12.

As shown in FIG. 2, the plural devices housed inside the module case 32 of the first autonomous driving module 30A include an autonomous driving control ECU 34 serving as an autonomous driving control device, a driver monitor ECU 38 serving as a driver information acquisition device, a high-definition map information ECU 40 serving as a position information acquisition device, and external sensors 42 that detect information about the area around the vehicle 12. Furthermore, the plural devices housed inside the module case 32 of the second autonomous driving module 30B include a low-voltage DC/DC converter 36 serving as a voltage conversion device, an auxiliary battery 52, and external sensors 42 that detect information about the area around the vehicle 12. It will be noted that FIG. 2 shows a state in which upper covers of the module cases 32 are detached.

The autonomous driving control ECU 34, the low-voltage DC/DC converter 36, the driver monitor ECU 38, and the high-definition map information ECU 40 have cuboidal outer shapes that are flat in the up and down direction, and the auxiliary battery 52 has a cuboidal outer shape whose dimension in the up and down direction is slightly larger than that of the ECUs 34, 38, and 40 and the converter 36. Inside the module case 32 of the first autonomous driving module 30A, an external sensor 42, the driver monitor ECU 38, the high-definition map information ECU 40, the autonomous driving control ECU 34, and an external sensor 42 are sequentially disposed from the vehicle front side to the vehicle rear side. Inside the module case 32 of the second autonomous driving module 30B, an external sensor 42, the low-voltage DC/DC converter 36, the auxiliary battery 52, and an external sensor 42 are sequentially disposed from the vehicle front side to the vehicle rear side. The ECUs 34, 38, and 40, the converter 36, the auxiliary battery 52, and the external sensors 42 are secured to the module cases 32 via brackets not shown in the drawings. It will be noted that this arrangement of the devices inside the module cases 32 is merely an example and can be changed as appropriate.

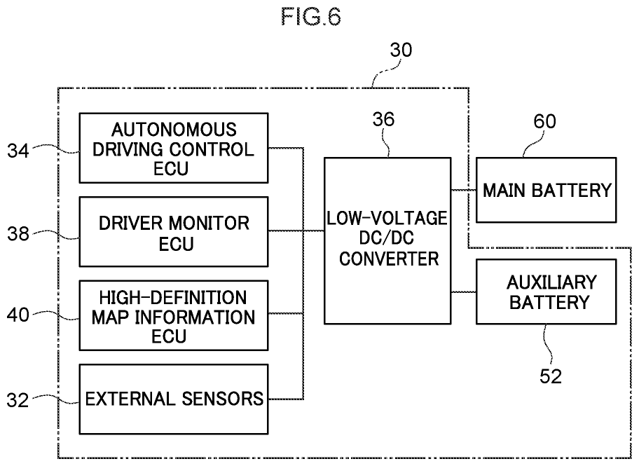

As shown in FIG. 6, the autonomous driving control ECU 34, the driver monitor ECU 38, the high-definition map information ECU 40, and the external sensors 42 are electrically connected to the low-voltage DC/DC converter 36. Also electrically connected to the low- voltage DC/DC converter 36 are a main battery 60, which is a vehicle driving battery that supplies power to an electric motor and is disposed in the cabin of the vehicle 12, and the auxiliary battery 52. These are interconnected via the input/output ports 50 and the wire harnesses (not shown in the drawings). It will be noted that the ECUs 34, 38, and 40 as well as the plural devices inside the first autonomous driving module 30A and the plural devices inside the second autonomous driving module 30B are connected to each other by known technologies such as wired and wireless.

The autonomous driving control ECU 34 controls autonomous driving by the vehicle 12 and controls switching between autonomous driving and manual driving. The driver monitor ECU 38 acquires driver information representing the state of the driver. The high- definition map information ECU 40 acquires information about the position of the vehicle 12 (the host vehicle) using map information and GPS information. These ECUs 34, 38, and 40 are all configured by a microcomputer including a central processing unit (CPU), a random-access memory (RAM), and a read-only memory (ROM), and transfer programs stored beforehand in the ROM to the RAM and execute them with the CPU. The driver monitor ECU 38 monitors the state of the driver based on information from an in-vehicle camera that captures an image of the driver and various sensors (none of which are shown in the drawings) provided in the driver's seat and the like. The high-definition map information ECU 40 is configured to include a hard disk in which a map database is formed and a GPS receiver (none of which are shown in the drawings).

The external sensors 42 detect information about the area around the vehicle 12 and detect, as the information about the area around the vehicle 12, imaging information obtained by external cameras, obstacle information obtained by radar, and obstacle information obtained by laser imaging detecting and ranging (LIDAR). As shown in FIG. 1 and FIG. 2, the external sensors 42 are disposed on both end portions in the vehicle front-rear direction and both end portions in the vehicle width direction to acquire data about the area all around the vehicle 12. It will be noted that the module cases 32 are provided with openings (not shown in the drawings) so that the cameras of the external sensors 42 and the like are exposed through the module cases 32.

The auxiliary battery 52 is an auxiliary power supply for the autonomous driving system 11 including the ECUs 34, 38, and 40. The auxiliary battery 52 has basically the same configuration as that of the main battery 60, but is configured to be sufficiently smaller than the main battery 60. The low-voltage DC/DC converter 36 performs power supply switching control to switch the power supply for the autonomous driving system 11 between the main battery 60 and the auxiliary battery 52 and converts the voltage of the auxiliary battery 52.

As shown in FIG. 7, the driver monitor ECU 38 and the high-definition map information ECU 40 are connected to the autonomous driving control ECU 34, and the external sensors 42, an internal sensor 44, actuators 46, auxiliary devices 48, and a human-machine interface (HMI) 54 are connected to the autonomous driving control ECU 34 via an in-vehicle network such as a controller area network (CAN).

The internal sensor 44 detects the driving state of the vehicle 12 and includes at least one of a vehicle speed sensor, an acceleration sensor, and a yaw rate sensor. The actuators 46 drive the accelerator pedal, brakes, and steering wheel of the vehicle 12. The auxiliary devices 48 include the headlamps, brake lamps, and turn signal lamps of the vehicle 12. The HMI 54 is an interface for the input and output of information between the occupant of the vehicle 12 and the autonomous driving system 11, and includes a display, speakers, touch panel, and voice input device.

The autonomous driving control ECU 34 performs an autonomous driving control process that controls the activation of the actuators 46 and the auxiliary devices 48 based on output from the driver monitor ECU 38, the high-definition map information ECU 40, the external sensors 42, the internal sensor 44, and the HMI 54. The autonomous driving control process generates a driving plan following a preset target route based on the information about the area around the vehicle 12 and the map information and controls the driving of the vehicle 12 so that the vehicle 12 drives autonomously in accordance with the generated driving plan.

As shown in FIG. 1, the autonomous driving module 30 having the above configuration is disposed between a front pillar P1 and a rear pillar P2 in the vehicle front- rear direction in top view. Here, P1 and P2, which are indicated by long dashed short dashed lines, represent the positions of the front pillar and the rear pillar, respectively. The autonomous driving module 30 is disposed on the rear side of a crumple area (crumple zone) that is designated at the front end portion of the vehicle 12 (in FIG. 1, the vehicle front side of the long dashed short dashed line P1) and is disposed on the front side of a crumple area (crumple zone) that is designated at the rear end portion of the vehicle 12 (in FIG. 1, the vehicle rear side of the long dashed short dashed line P2). The crumple areas are areas that absorb the energy of an impact by crumpling in the vehicle front-rear direction at the time of a frontal impact or at the time of a rear impact to the vehicle 12. In other words, the autonomous driving module 30 is disposed in a safety area (safety zone) that has enough strength to maintain its shape even when subjected to a shock at the time of a frontal impact or at the time of a rear impact to the vehicle 12.

(Action and Effects of First Embodiment)

Next, the action and effects of the first embodiment will be described.

In the first embodiment, as shown in FIG. 1, the autonomous driving module mounting structure 10 includes the autonomous driving module 30 that is configured by the integration of plural devices, and the autonomous driving module 30 allows the vehicle 12 to drive autonomously. Furthermore, the autonomous driving module 30 is configured by the modularization of the plural devices that are constituent devices of the autonomous driving system 11, so compared to a case where the plural devices are individually mounted in the vehicle, a reduction in mounting space becomes possible. As a result, the cabin space can be inhibited from being reduced.

Furthermore, the autonomous driving module 30 is mounted on the upper surface of the outer section of the roof panel 16 and is disposed in a position that does not coincide with the open portion 18 provided in the roof panel 16 in top view. When the open portion 18 is provided with the sunroof 20, the autonomous driving module 30 does not obstruct the opening and closing of the sunroof 20. Because of this, the autonomous driving module 30 can be mounted on the roof panel 16 while allowing the sunroof 20 to be opened and closed.

Furthermore, the open portion 18, which is disposed in a position that does not coincide with the autonomous driving module 30 in top view, is provided with the sunroof 20 that can be opened and closed. The autonomous driving module 30 does not obstruct the opening and closing of the sunroof 20, so the autonomous driving module 30 can be mounted on the roof panel 16 while allowing the sunroof 20 to be opened and closed.

Furthermore, the autonomous driving modules 30A and 30B are disposed along the vehicle front-rear direction on both sides in the vehicle width direction of the open portion 18 in top view. The frontal projected area from the vehicle front side can be reduced, as the autonomous driving module 30 is not mounted on the vehicle front side and the vehicle rear side of the open portion 18, and air resistance can be reduced. Furthermore, since the autonomous driving module is not mounted on the vehicle front side and the vehicle rear side of the open portion 18, the autonomous driving modules 30A and 30B are unlikely to sustain damage at the time of an impact in the front-rear direction to the vehicle 12.

Furthermore, the autonomous driving modules 30A and 30B are disposed between the front pillar P1 and the rear pillar P2 in the vehicle front-rear direction in top view. The area between the front pillar P1 and the rear pillar P2 in the vehicle front-rear direction is included in the safety zone that has enough strength to maintain its shape even when subjected to a shock. The crash safety performance of the autonomous driving modules 30A and 30B at the time of an impact to the vehicle can be improved.

Furthermore, the upper surface of the outer section of the roof panel 16 is provided with the input/output ports 50 to which wiring or devices from the autonomous driving modules 30A and 30B can be connected, so when, for example, the technology of the sensors and the like included in the autonomous driving modules 30A and 30B has improved, the autonomous driving modules 30A and 30B can be easily updated.

Furthermore, the module cases 32 each have the sloping portion 33 that descends from the vehicle rear side to the vehicle front side in side view. Air resistance experienced by the vehicle 12 from the front when the vehicle 12 moves forward can be kept down by the sloping portions 33, and aerodynamic performance of the vehicle 12 can be improved.

Next, other embodiments pertaining to the disclosure will be described. Autonomous driving module mounting structures 10 of the other embodiments differ from that of the first embodiment in terms of the configuration of the module case(s) 32 housing the autonomous driving module 30. It will be noted that, below, in regard to the autonomous driving module mounting structures 10 of the other embodiments, configurations that are the same as those in the first embodiment described above are assigned the same reference signs and detailed description is omitted.

### Second Embodiment

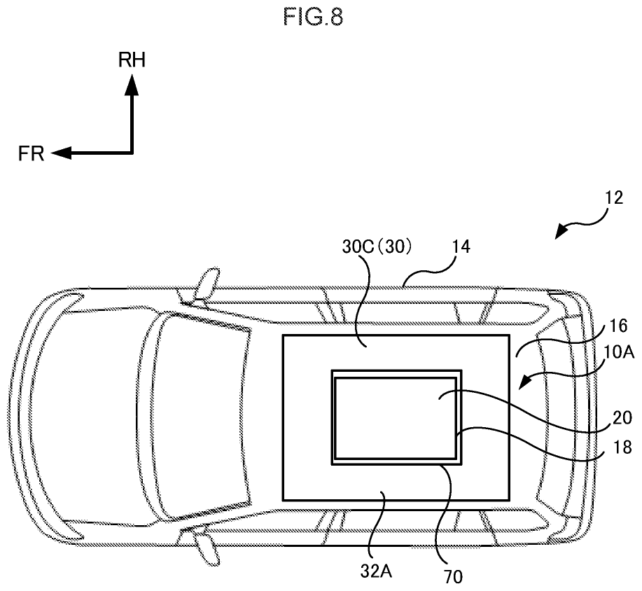

An autonomous driving module mounting structure 10A of a second embodiment pertaining to the disclosure will be described. FIG. 8 is a top view of the vehicle 12 to which the autonomous driving module mounting structure 10A is applied.

As shown in FIG. 8, the autonomous driving module mounting structure 10A of the second embodiment includes one autonomous driving module 30C. The autonomous driving module 30C is configured as a result of plural devices being housed inside a module case 32A serving as an outer shell. The module case 32A has the shape of a hollow cuboid whose lengthwise direction coincides with the vehicle front-rear direction, and has an opening 70 in its central portion. That is, the autonomous driving module 30C is disposed along the vehicle front-rear direction at both sides in the vehicle width direction of the open portion 18 in top view and along the vehicle width direction at both sides in the vehicle front-rear direction of the open portion 18 in top view. In other words, the autonomous driving module 30C is disposed surrounding the open portion 18. Furthermore, the module case 32A has, as in the first embodiment, a sloping portion 33 that descends from the vehicle rear side to the vehicle front side in side view (see FIG. 3). Furthermore, although this is not shown in the drawing, the upper surface of the outer section of the roof panel 16 is, as in the first embodiment, provided with the input/output ports 50 to which wiring or devices from the autonomous driving module 30C can be connected (see FIG. 1).

Inside the module case 32A are housed at least the same devices as the plural devices housed in the module cases 32 of the autonomous driving modules 30A and 30B of the first embodiment. The arrangement of the devices is not particularly limited, and the devices are arranged so as to be changeable as appropriate depending on the number and sizes of the plural devices.

(Action and Effects of Second Embodiment)

Next, the action and effects of the second embodiment will be described.

According to the autonomous driving module mounting structure 10A of the second embodiment, the autonomous driving module 30C is disposed along the vehicle front-rear direction at both sides in the vehicle width direction of the open portion 18 in top view and along the vehicle width direction at both sides in the vehicle front-rear direction of the open portion 18 in top view. That is, the autonomous driving module 30C is disposed surrounding the open portion 18. For that reason, compared to the autonomous driving module mounting structure 10 of the first embodiment, the mounting area of the autonomous driving module 30C can be increased by the amount that the autonomous driving module 30C is disposed along the vehicle width direction at both sides in the vehicle front-rear direction of the open portion 18. Because of this, the number of the devices included in the autonomous driving module 30C can be increased, so the performance of the autonomous driving module 30C can be improved.

### Third Embodiment

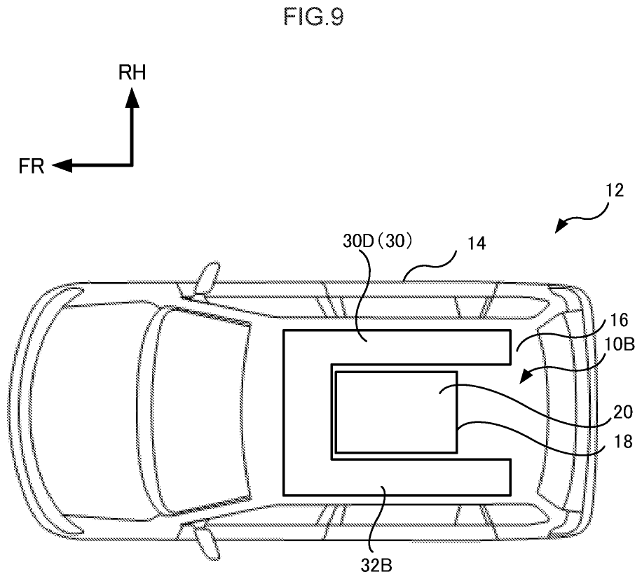

Next, an autonomous driving module mounting structure 10B of a third embodiment pertaining to the disclosure will be described. FIG. 9 is a top view of the vehicle 12 to which the autonomous driving module mounting structure 10B is applied.

As shown in FIG. 9, the autonomous driving module mounting structure 10B of the third embodiment includes one autonomous driving module 30D. The autonomous driving module 30D is configured as a result of plural devices being housed inside a module case 32B serving as an outer shell. The module case 32B is thick in the vehicle up and down direction and has the shape of a sideways “U” that is open in the vehicle rearward direction. The module case 32B has, as in the first embodiment, a sloping portion 33 that descends from the vehicle rear side to the vehicle front side in side view (see FIG. 3). Furthermore, although this is not shown in the drawing, the upper surface of the outer section of the roof panel 16 is, as in the first embodiment, provided with the input/output ports 50 to which wiring or devices from the autonomous driving module 30D can be connected (see FIG. 1).

Inside the module case 32B are housed at least the same devices as the plural devices housed in the module cases 32 of the autonomous driving modules 30A and 30B of the first embodiment. The arrangement of the devices is not particularly limited, and the devices are arranged so as to be changeable as appropriate depending on the number and sizes of the plural devices.

(Action and Effects of Third Embodiment)

Next, the action and effects of the third embodiment will be described.

According to the autonomous driving module mounting structure 10B of the third embodiment, the autonomous driving module 30D is disposed along the vehicle front-rear direction at both sides in the vehicle width direction of the open portion 18 in top view and along the vehicle width direction at the vehicle front side of the open portion 18 in top view. For that reason, compared to the autonomous driving module mounting structure 10 of the first embodiment, the mounting area of the autonomous driving module can be increased by the amount that the autonomous driving module 30D is disposed along the vehicle width direction at the vehicle front side of the open portion 18. Because of this, the number of the devices included in the autonomous driving module 30D can be increased, so the performance of the autonomous driving module 30D can be improved.

Furthermore, according to the autonomous driving module mounting structure 10B, the autonomous driving module 30D is not mounted at the vehicle rear side of the open portion 18, so the autonomous driving module 30D is unlikely to sustain damage at the time of an impact from the rear direction to the vehicle 12.

### Fourth Embodiment

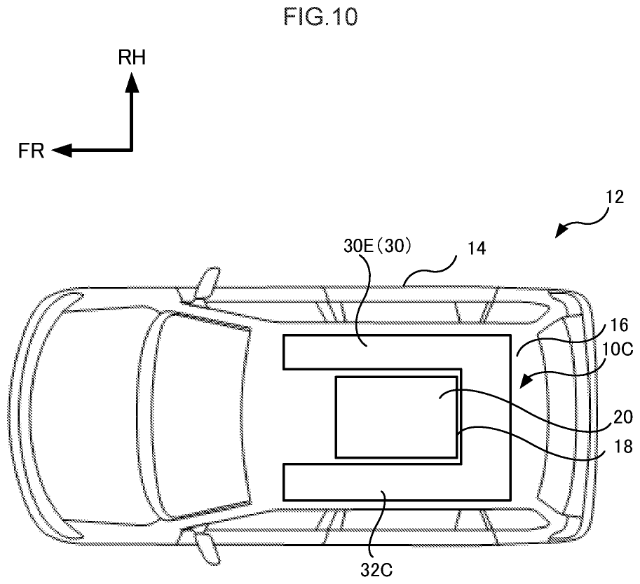

Next, an autonomous driving module mounting structure 10C of a fourth embodiment pertaining to the disclosure will be described. FIG. 10 is a top view of the vehicle 12 to which the autonomous driving module mounting structure 10C pertaining to the fourth embodiment is applied.

As shown in FIG. 10, the autonomous driving module mounting structure 10C of the fourth embodiment includes one autonomous driving module 30E. The autonomous driving module 30E is configured as a result of plural devices being housed inside a module case 32C serving as an outer shell. The module case 32C is thick in the vehicle up and down direction and has the shape of a sideways “U” that is open in the vehicle forward direction. The module case 32C has, as in the first embodiment, sloping portions 33 that descend from the vehicle rear side to the vehicle front side in side view (see FIG. 3). Furthermore, although this is not shown in the drawing, the upper surface of the outer section of the roof panel 16 is, as in the first embodiment, provided with the input/output ports 50 to which wiring or devices from the autonomous driving module 30E can be connected (see FIG. 1).

Inside the module case 32C are housed at least the same devices as the plural devices housed in the module cases 32 of the autonomous driving modules 30A and 30B of the first embodiment. The arrangement of the devices is not particularly limited, and the devices are arranged so as to be changeable as appropriate depending on the number and sizes of the plural devices.

(Action and Effects of Fourth Embodiment)

Next, the action and effects of the fourth embodiment will be described.

According to the autonomous driving module mounting structure 10C of the fourth embodiment, the autonomous driving module 30E is disposed along the vehicle front-rear direction at both sides in the vehicle width direction of the open portion 18 in top view and along the vehicle width direction at the vehicle rear side of the open portion 18 in top view. For that reason, compared to the autonomous driving module mounting structure 10 of the first embodiment, the mounting area of the autonomous driving module can be increased by the amount that the autonomous driving module 30E is disposed along the vehicle width direction at the vehicle rear side of the open portion 18. Because of this, the number of the devices included in the autonomous driving module 30E can be increased, so the performance of the autonomous driving module 30E can be improved.

Furthermore, according to the autonomous driving module mounting structure 10C of the fourth embodiment, the autonomous driving module 30E is not mounted on the vehicle front side of the open portion 18, so the autonomous driving module 30E is unlikely to sustain damage at the time of an impact from the front direction to the vehicle 12.

(Fifth to Eighth Embodiments)

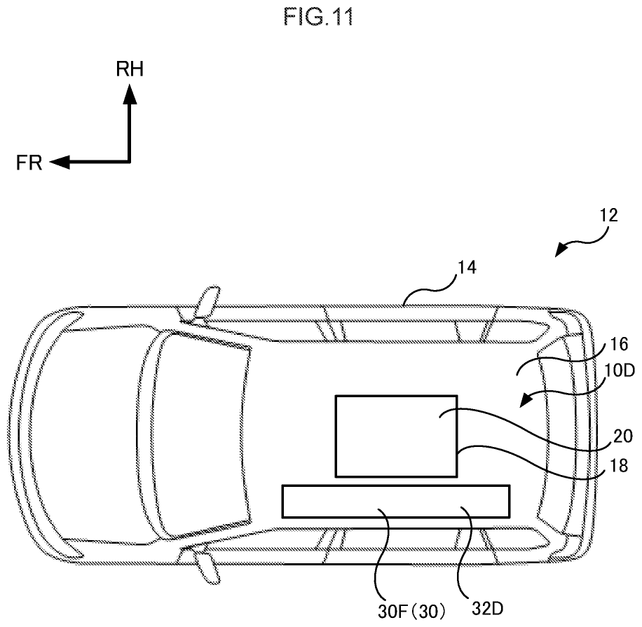

Next, autonomous driving module mounting structures 10D, 10E, 10F, and 10G of fifth to eighth embodiments pertaining to the disclosure will be described. FIG. 11 to FIG. 14 are top views of the vehicle 12 to which the autonomous driving module mounting structures 10D, 10E, 10F, and 10G pertaining to the fifth to eighth embodiments are applied.

As shown in FIG. 11, the autonomous driving module mounting structure 10D of the fifth embodiment includes one autonomous driving module 30F. The autonomous driving module 30F is configured as a result of plural devices being housed inside a module case 32D serving as an outer shell. The module case 32D has the shape of a long hollow cuboid whose lengthwise direction coincides with the vehicle front-rear direction, and is disposed along the vehicle front-rear direction at the left side in the vehicle width direction of the open portion 18.

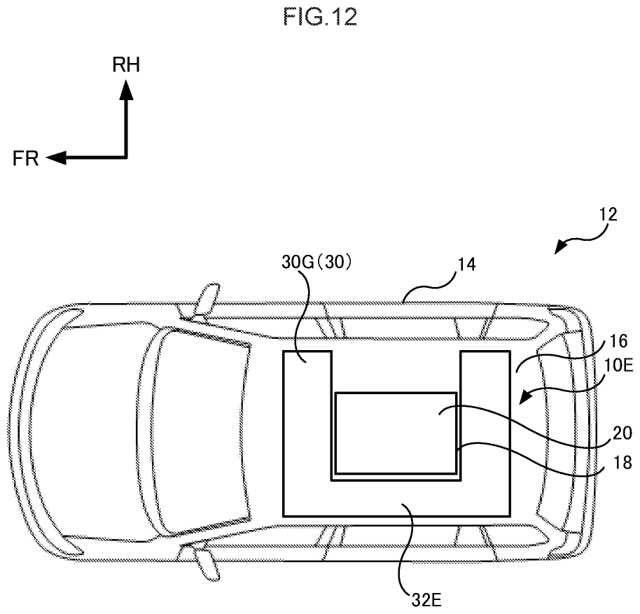

As shown in FIG. 12, the autonomous driving module mounting structure 10E of the sixth embodiment includes one autonomous driving module 30G. The autonomous driving module 30G is configured as a result of plural devices being housed inside a module case 32E serving as an outer shell. The module case 32E is thick in the vehicle up and down direction and has the shape of a sideways “U” that is open rightward in the vehicle width direction.

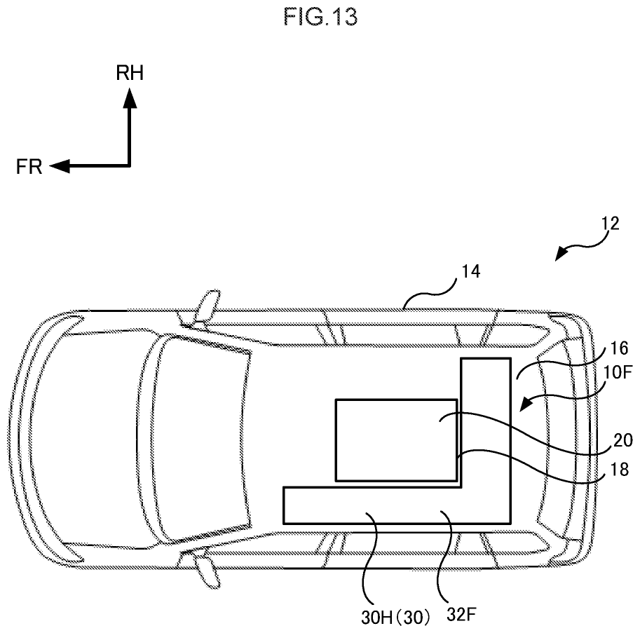

As shown in FIG. 13, the autonomous driving module mounting structure 10F of the seventh embodiment includes one autonomous driving module 30H. The autonomous driving module 30H is configured as a result of plural devices being housed inside a module case 32F serving as an outer shell. The module case 32F is thick in the vehicle up and down direction and has the shape of an “L” that is open in the vehicle forward direction and rightward in the vehicle width direction.

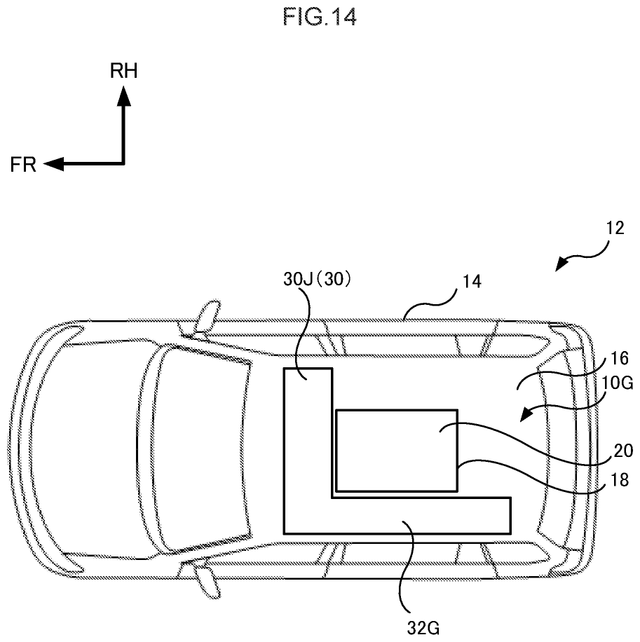

As shown in FIG. 14, the autonomous driving module mounting structure 10G of the eighth embodiment includes one autonomous driving module 30J. The autonomous driving module 30J is configured as a result of plural devices being housed inside a module case 32G serving as an outer shell. The module case 32G is thick in the vehicle up and down direction and has the shape of an “L” that is open in the vehicle rearward direction and rightward in the vehicle width direction.

The module cases 32D, 32E, 32F, and 32G of the fifth to eighth embodiments have, as in the first embodiment, sloping portions 33 that descend from the vehicle rear side to the vehicle front side in side view (see FIG. 3). Furthermore, although this is not shown in the drawings, the upper surface of the outer section of the roof panel 16 is, as in the first embodiment, provided with the input/output ports 50 to which wiring or devices from the autonomous driving modules 30F, 30G, 30H, and 30J can be connected (see FIG. 1).

(Action and Effects of Fifth to Eighth Embodiments)

Next, the action and effects of the fifth to eighth embodiments will be described.

As shown in FIG. 1 and FIG. 8 to FIG. 10, in the autonomous driving module mounting structures 10, 10A, 10B, and 10C of the first to fourth embodiments, the autonomous driving modules 30 (30A, 30B), 30C, 30D, and 30E are mounted so as to be bilaterally symmetrical in the vehicle width direction. In contrast, in the autonomous driving module mounting structures 10D, 10E, 10F, and 10G of the fifth to eighth embodiments, as shown in FIG. 11 to FIG. 14, the autonomous driving modules 30F, 30G, 30H, and 30J are mounted concentrating on the vehicle left side.

For example, in a case where the driving lane is restricted a certain extent (as an example, to the left side) as with vehicles such as fixed-route buses and trucks, data in a predetermined direction, such as information about the area around the vehicle 12, can be reliably acquired while reducing the weight of the autonomous driving module mounting structures 10D, 10E, 10F, and 10G. Furthermore, costs required for the module case 32 serving as the outer shell and costs required for the various sensors can be kept down.

(Ninth and Tenth Embodiments)

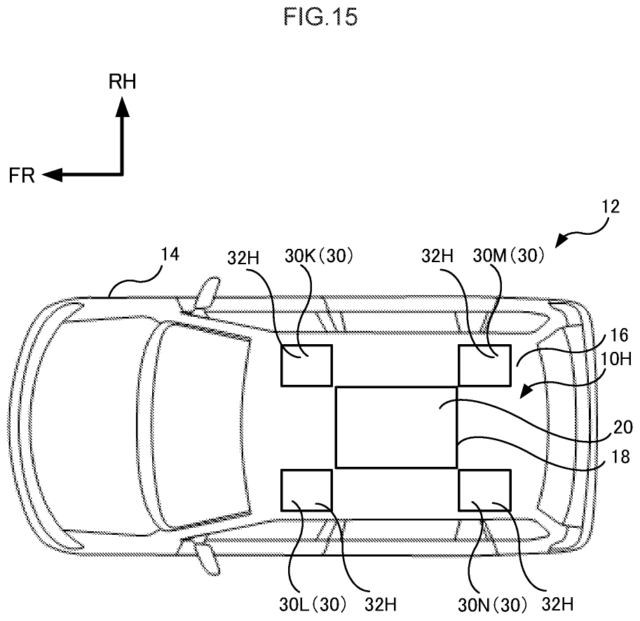

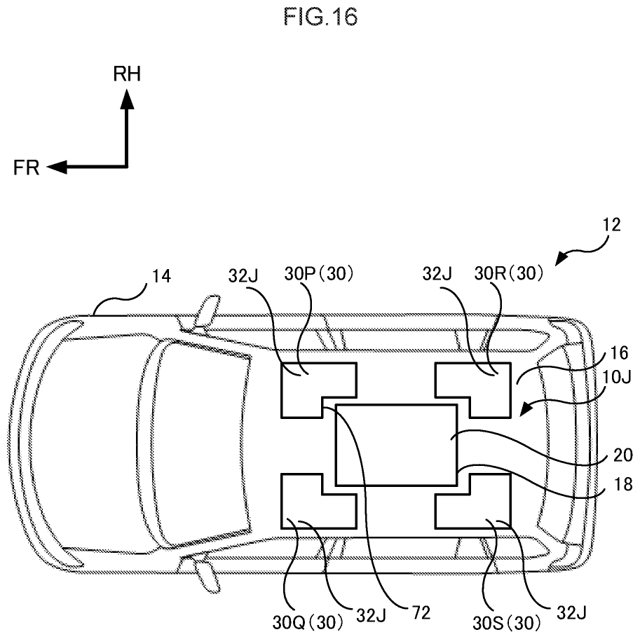

Next, autonomous driving module mounting structures 10H and 10J of ninth and tenth embodiments pertaining to the disclosure will be described. FIG. 15 and FIG. 16 are top views of the vehicle 12 to which the autonomous driving module mounting structures 10H and 10J pertaining to the ninth and tenth embodiments is applied.

As shown in FIG. 15, the autonomous driving module mounting structure 10H of the ninth embodiment includes four autonomous driving modules 30K, 30L, 30M, and 30N. The autonomous driving modules 30K, 30L, 30M, and 30N are each configured by plural devices housed inside a module case 32H serving as an outer shell. The module cases 32H each have the shape of a hollow cuboid and are disposed in the vicinities of the four corners of the open portion 18.

As shown in FIG. 16, the autonomous driving module mounting structure 10J of the tenth embodiment includes four autonomous driving modules 30P, 30Q, 30R, and 30S. The autonomous driving modules 30P, 30Q, 30R, and 30S are each configured by plural devices housed inside a module case 32J serving as an outer shell. The module cases 32J each have the shape of a hollow cuboid, each have a rectangular cutout portion 72 in their corner portion on the open portion 18 side, and are disposed in the vicinities of the four corners of the open portion 18.

In the module cases 32H of the ninth embodiment the devices in the autonomous driving modules 30K, 30L, 30M, and 30N are communicably connected to each other by wires or wireles sly, and in the module cases 32J of the tenth embodiment the devices in the autonomous driving modules 30P, 30Q, 30R, and 30S are communicably connected to each other by wires or wireles sly. Furthermore, although this is not shown in the drawings, the upper surface of the outer section of the roof panel 16 is, as in the first embodiment, provided with the input/output ports 50 to which wiring or devices from at least one of the autonomous driving modules 30K, 30L, 30M, and 30N; and 30P, 30Q, 30R, and 30S can be connected (see FIG. 1).

(Action and Effects of Ninth and Tenth Embodiments)

Next, the action and effects of the ninth and tenth embodiments will be described.

In the autonomous driving module mounting structures 10H and 10J of the ninth and tenth embodiments, as shown in FIG. 15 and FIG. 16, the module cases 32H and 32J are disposed in the vicinities of the four corners of the open portion 18 on the upper surface of the outer section of the roof panel 16. Because of this, the risk of damage to the devices housed inside the module cases 32H and 32J at the time of an impact to the vehicle 12 can be reduced.

### <Supplemental Description of Above Embodiments>

(1) In the above embodiments, the autonomous driving control ECU 34, the driver monitor ECU 38, and the high-definition map information ECU 40 were separate from each other, but depending on, for example, the configuration of the module case, the autonomous driving control ECU 34, the driver monitor ECU 38, and the high-definition map information ECU 40 may also be integrated.

(2) In the above embodiments, the autonomous driving modules 30 were disposed between the front pillar and the rear pillar in the vehicle front-rear direction in top view, that is, in the safety zone, but the disclosure is not limited to this. The autonomous driving modules 30 may also be disposed outside the safety zone.

(3) In the above embodiments, the module cases 32 were mounted to the roof rails 19, but the disclosure is not limited to this. For example, the roof rails 19 may be detached and the module cases 32 may be mounted in place of the roof rails 19. Furthermore, the module cases may be fastened with bolts or mounted by welding to the roof panel 16. In some embodiments, the module cases 32 may be detachably mounted to the roof panel 16 so that the various devices can be easily replaced when their performance, such as the performance of the sensors, has improved.

(4) In the above embodiments, the external sensors 42 are disposed inside the module cases 32, but the disclosure is not limited to this. The external sensors 42 may also be disposed somewhere on the vehicle 12 rather than inside the module cases 32.

(5) In the fifth to eighth embodiments, the autonomous driving modules 30F, 30G, 30H, and 30J were mounted concentrating on the vehicle left side, but the disclosure is not limited to this. For example, in a case where the driving lane of the vehicle is on the right side, the autonomous driving modules 30F, 30G, 30H, and 30J can also be mounted concentrating on the vehicle right side.

(6) Furthermore, the shape of the module case(s) is not limited to the shapes in the above embodiments, and the module case(s) can take various shapes, such as an oval shape as seen from the vehicle up and down direction, depending on the specifications of the vehicle 12 and the configurations of the devices housed in the module case.

(7) Furthermore, in a case where the autonomous driving module 30 is housed in two or more module cases, the way in which the plural devices included in the autonomous driving module 30 are divided between the module cases is not particularly limited and can be changed as appropriate depending on the specifications and sizes of the devices.

(8) Furthermore, the method of arranging the plural devices housed inside the module case(s) is not particularly limited and can be appropriately changed depending on the specifications and sizes of the devices.

(9) Furthermore, the present disclosure can be changed in various ways and implemented in a range that does not depart from the scope thereof. Furthermore, the scope of the disclosure is of course not limited to the above embodiments.

What is claimed is:

1. An autonomous driving module mounting structure, comprising:
a roof panel configuring an upper portion of a vehicle body;
an open portion provided at the roof panel; and
an autonomous driving module that includes a plurality of devices, that is mounted on an upper surface of an outer section of the roof panel, and that is disposed at a position that does not coincide with the open portion in top view.

2. The autonomous driving module mounting structure of claim 1, wherein the open portion is provided with a sunroof that can be opened and closed.

3. The autonomous driving module mounting structure of claim 1, wherein the autonomous driving module is disposed along a vehicle front-rear direction on at least one of respective sides in a vehicle width direction of the open portion in top view.

4. The autonomous driving module mounting structure of claim 1, wherein the autonomous driving module is disposed along a vehicle front-rear direction on at least one of respective sides in a vehicle width direction of the open portion in top view and along the vehicle width direction on at least one of respective sides in the vehicle front-rear direction of the open portion in top view.

5. The autonomous driving module mounting structure of claim 1, wherein the autonomous driving module is disposed between a front pillar and a rear pillar in a vehicle front-rear direction in top view.

6. The autonomous driving module mounting structure of claim 1, wherein the upper surface of the outer section of the roof panel is provided with input/output ports to which wiring or devices from the autonomous driving module can be connected.

7. The autonomous driving module mounting structure of claim 1, wherein the autonomous driving module mounting structure has at least one module case that houses the autonomous driving module, and the module case has a sloping portion that descends from a vehicle rear side to a vehicle front side in side view.

8. The autonomous driving module mounting structure of claim 2, wherein the autonomous driving module mounting structure has at least one module case that houses the autonomous driving module, and the module case has a sloping portion that descends from a vehicle rear side to a vehicle front side in side view.

9. The autonomous driving module mounting structure of claim 3, wherein the autonomous driving module mounting structure has at least one module case that houses the autonomous driving module, and the module case has a sloping portion that descends from a vehicle rear side to a vehicle front side in side view.

10. The autonomous driving module mounting structure of claim 4, wherein the autonomous driving module mounting structure has at least one module case that houses the autonomous driving module, and the module case has a sloping portion that descends from a vehicle rear side to a vehicle front side in side view.

11. The autonomous driving module mounting structure of claim 5 wherein the autonomous driving module mounting structure has at least one module case that houses the autonomous driving module, and the module case has a sloping portion that descends from a vehicle rear side to a vehicle front side in side view.

12. The autonomous driving module mounting structure of claim 6, wherein the autonomous driving module mounting structure has at least one module case that houses the autonomous driving module, and the module case has a sloping portion that descends from a vehicle rear side to a vehicle front side in side view.

13. The autonomous driving module mounting structure of claim 1, wherein four autonomous driving modules are disposed in vicinities of four corners of the open portion in top view.
